(19) United States
(12) Patent Application Publication
(10) Pub. No.: US 2005/0185465 A1
(43) Pub. Date: Aug. 25, 2005

(54) Memory device

(75) Inventors: Nobutaka Taniguchi, Kawasaki (JP); Atsushi Hatakeyama, Kawasaki (JP); Toshimi Ikeda, Kawasaki (JP); Akira Kikutake, Kawasaki (JP); Kuninori Kawabata, Kawasaki (JP); Atsushi Takeuchi, Kawasaki (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/110,700

(22) Filed: Apr. 21, 2005

Related U.S. Application Data
(63) Continuation of application No. PCT/JP03/02832, filed on Mar. 11, 2003.

(51) Int. Cl. G11C 11/34

(52) U.S. Cl. 365/185.11

(57) ABSTRACT

A memory device includes plural banks (BNKA, BNKB, BNKC, and BNKD), and each of the banks includes a plural memory cells storing data and plural bit lines reading data from the plural memory cells. Bit line lengths of all of the plural banks are equal.

### TECHNICAL FIELD

The present invention relates to a memory device, particularly to a memory device including plural banks.

### BACKGROUND ART

A flash memory includes nonvolatile memory cells, and data is erased and written in units of sectors each having plural memory cells. Operation modes of the flash memory includes: a read mode of reading data from selected one or plural memory cells; an erase mode of writing a data “1” on all memory cells of a selected sector; and a program (write) mode of writing a data “0” on selected one or plural memory cells.

In the above-mentioned program mode and erase mode, a stress applying process of applying a constant high potential to memory cells having a floating gate and a verifying process of verifying a change in a threshold voltage of the memory cells are repeated until a desired data is written. In other words, in the program mode, a positive high potential is applied to a control gate, so that electrons are injected to a floating gate until reaching a threshold voltage which is equal to or higher than a predetermined value. In the erase mode, a positive high potential is applied to a substrate side as back bias, so that electrons are emitted from the floating gate until reaching a threshold voltage which is equal to or lower than a predetermined value. Therefore, in the flash memory, while a program or erase operation is being performed on a sector of a bank, a read operation cannot be performed on memory cells of another sector of the bank.

Further, program and erase operations take longer time than a read operation. Therefore, when a program or erase operation is started on a bank, a memory area from which data can be read reduces, thereby placing constraints on a read operation.

In order to ease the constraints, a flash memory including many banks is demanded. By increasing the number of banks, a capacity of a memory that is inaccessible during a program or erase operation can be reduced.

Further, the flash memory is a nonvolatile memory capable of holding stored data even in a power-off state. With this feature, the flash memory is often used as a semiconductor memory for storing a boot program, which is initially accessed at power-up. Accordingly, the flash memory often includes a bank having a boot sector accessed at power-up and a bank having other ordinary sectors.

In that case, bank configurations suitable for various applications of users are required, e.g., a flash memory in which a capacity of a bank having a boot sector is smaller than that of another bank, and a flash memory in which a capacity of a bank having a boot sector is equal to that of another bank, depending on a size of the boot program.

In order to satisfy these two requirements at the same time and to meet various needs, the following method has been proposed. That is, a combination of plural real banks is changed in each model of flash memories, so that plural combinations of virtual banks are realized.

As described above, the flash memory typically includes many banks to reduce a capacity of a memory which is inaccessible during a program or erase operation. Also, in order to meet various purposes, the flash memory has a function of changing a combination of banks in each model so that a ratio between a capacity of a bank having a boot sector and a capacity of another bank can be freely designed.

Herein, “freely designed” means realizing several combinations of virtual banks. For example, when the flash memory includes four real banks (a capacity ratio is 1:3:3:1), two virtual banks (a capacity ratio is 1:7, 2:6, or 4:4) or four virtual banks (a capacity ratio is 1:3:3:1) may be realized. However, a form of each bank is different depending on a configuration of virtual banks, which often causes variations in bit line lengths.

In a typical flash memory, a read operation is performed by converting a small current in a memory cell transistor to a potential and comparing the potential with a reference potential. However, when a bit line is long, a parasitic capacity of a selected bit line is large, so that a potential conversion is slowly performed. As a result, it takes time to obtain a difference potential enough for being compared with the reference potential. This means that a data reading speed is the lowest in a combination of virtual banks where a bit line length is the longest.

### SUMMARY OF THE INVENTION

An object of the present invention is to provide a memory device capable of realizing an optimum reading speed regardless of a configuration of virtual banks.

According to an aspect of the present invention, a memory device including plural banks is provided. Each bank includes plural memory cells storing data; and plural bit lines reading data from the plural memory cells. Bit line lengths of all of the plural banks are equal to each other.

Since the bit line lengths of all of the banks are equal to each other, an access speed of the entire memory device can be improved. Further, since the bit line lengths of all of the virtual banks can be made equal to each other regardless of the form of the virtual banks, each being a combination of real banks, high-speed reading can be consistently performed.

### BRIEF DESCRIPTION OF THE DRAWINGS

FIG. 1 is a view showing an example of a configuration of a real bank in a flash memory according to an embodiment of the present invention.

FIG. 2 is a view showing an example of a hierarchical block configuration of the real bank according to the embodiment.

FIGS. 3A to 3D are views showing an example of a configuration of four types of flash memories.

FIGS. 4A and 4B are views showing an example of a configuration of real banks.

FIGS. 5A to 5D are views showing an example of a configuration of four types of flash memories according to the embodiment.

FIGS. 6A and 6B are views showing an example of a configuration of real banks according to the embodiment.

### DETAILED DESCRIPTION OF THE PREFERRED EMBODIMENTS

Hereinafter, an embodiment of the present invention will be described with reference to the drawings. The scope of the present invention to be protected is not limited to the following embodiment, but covers the invention described in the appended claims and equivalents thereof.

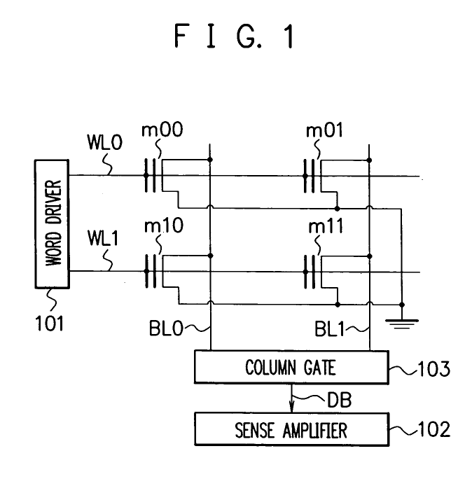

FIG. 1 is a view showing an example of a configuration of a real bank in a flash memory device according to the embodiment of the present invention. The real bank includes plural memory cells m00, m01, m10, and m11, each having a floating gate. The memory cells m00 to m11 are placed at intersections of word lines WL0 and WL1 and bit lines BL0 and BL1, respectively, and store data.

In the memory cell transistor m00, a control gate is connected to the word line WL0, a drain is connected to the bit line BL0, and a source is connected to a ground potential. In the memory cell transistor m01, a control gate is connected to the word line WL0, a drain is connected to the bit line BL1, and a source is connected to the ground potential. In the memory cell transistor m10, a control gate is connected to the word line WL1, a drain is connected to the bit line BL0, and a source is connected to the ground potential. In the memory cell transistor m11, a control gate is connected to the word line WL1, a drain is connected to the bit line BL1, and a source is connected to the ground potential.

The word lines WL0 and WL1 are driven by a word driver 101 in response to addressing. The bit lines BL0 and BL1 are connected to a data bus DB through a column gate 103. The column gate 103 connects one or plural bit lines selected from among the bit lines BL0, BL1, and so on to one or plural data buses DB in response to addressing. One of the memory cells m00 to m11 is selected by a selection of the word line WL0 or WL1 and the bit line BL0 or BL1. Data read from the selected memory cell m00 or the like is output to the data bus DB through the bit line BL0 or BL1. One or plural sense amplifiers 102 amplify data read to one or plural data buses DB.

In an erase mode, a threshold voltage of the memory cell transistors m00 and so on is low (data “1”). In a program mode, a negative charge is injected into a floating gate by controlling the word line WL0 or WL1 and the bit line BL0 or BL1 to a positive high potential, so that the threshold voltage is set to a high value. This state corresponds to a data “0”. At an erasing operation, by controlling the bit line BL0 or BL1 to an open state, the word line WL0 or WL1 to a ground potential, and a back bias to a positive high potential, a negative charge in the floating gate is extracted, so that the threshold voltage is set to a low value. This state corresponds to a data “1”. At a reading operation, an intermediate voltage between the two threshold voltages is applied to the word line WL0 or WL1, so that a large or small current flows through the bit line BL0 or BL1 according to a state of the threshold voltages. Accordingly, stored data is read.

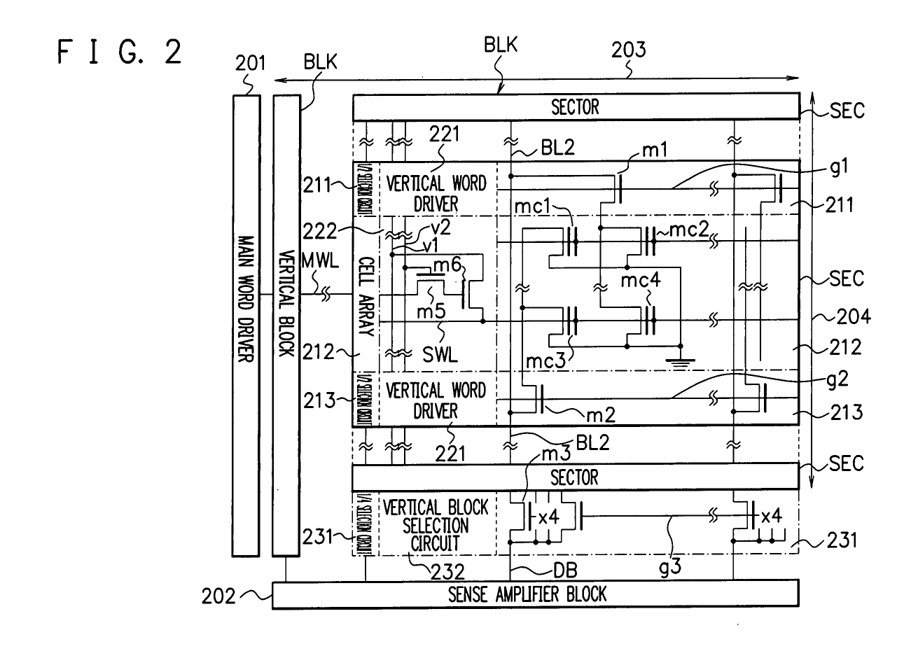

FIG. 2 is a view showing an example of a hierarchical block configuration of the real bank according to the embodiment. A main word driver 201 controls a voltage of a main word line MWL (a third metal layer) connected to plural vertical blocks BLK in response to addressing. A sense amplifier block 202 amplifies data read to a data bus DB. The plural vertical blocks BLK are aligned in a horizontal direction in an area 203. In each vertical block BLK, plural sectors SEC are aligned in a vertical direction in an area 204. Vertical word drivers 221 and a sub-driver 222 are placed at a central portion of the sector SEC. ½ selection circuits 211 and 213 and a cell array 212 are placed on the right and left of the sector.

Next, a reading method is described. A ¼ selection circuit 231 is described first. Four gate lines g3 are connected to gates of four n-channel MOS transistors m3, respectively. In response to addressing, one of the four gate lines g3 is turned to a high level and only one of the transistors m3 corresponding to the gate line g3 is turned on. Accordingly, the common data bus DB is connected to a bit line (a second metal layer) BL2. That is, one of four bit lines is selected. The bit line BL2 is connectable with memory cells mc1, mc2, mc3, and mc4. As a result of this selection, the four memory cells mc1, mc2, mc3, and mc4 are selected from among plural memory cells.

The main word driver 201 selects one main word line MWL and turns it to a high level in response to addressing. In an n-channel MOS transistor m5, a drain is connected to the main word line MWL, a source is connected to a gate of an n-channel MOS transistor m6, and a gate is connected to a second vertical word line v2. In a transistor m6, a drain is connected to a first vertical word line v1 and a source is connected to a sub word line (a second polysilicon layer) SWL. The second vertical word line v2 is turned to a high level and then the first vertical word line v1 is turned to a high level. Since the main word line MWL is at a high level, the transistors m5 and m6 are turned on and the sub word line SWL is turned to a high level. The sub word line SWL is connected to control gates of the memory cells mc3 and mc4. Accordingly, the memory cells mc3 and mc4 are selected from among the four memory cells mc1, mc2, mc3, and mc4. The vertical word driver 221 and a vertical block selection circuit 232 control voltages of the vertical word lines v1 and v2.

The ½ selection circuit 211 includes an n-channel MOS transistor m1. In the transistor m1, a gate is connected to a gate line g1, a drain is connected to the bit line BL2, and a source is connected to drains of the memory cell transistors mc2 and mc4. Sources of the memory cell transistors mc1 to mc4 are connected to a ground potential. The ½ selection circuit 213 includes an n-channel MOS transistor m2. In the transistor m2, a gate is connected to a gate line g2, a drain is connected to the bit line BL2, and a source is connected to drains of the memory cell transistors mc1 and mc3.

In response to addressing, any one of the gate lines g1 and g2 is turned to a high level. For example, the gate line g1 is turned to a high level, the transistor m1 is turned on, and the transistor m2 is turned off. Accordingly, the bit line BL2 is connected to the memory cell transistors mc2 and mc4. In this way, ½ selection is performed. By combining the ½ selection with the above-described ¼ selection, ⅛ selection is performed.

Further, since the sub word line SWL has been selected as described above, the memory cell mc4 is selected. A current according to a threshold voltage of the memory cell mc4 is flown through the bit line BL2 and the common data bus DB. The sense amplifier block 202 converts the current in the data bus DB to a voltage and amplifies the voltage, and then externally outputs the voltage as read data.

That is, when a threshold voltage is low (data “1”) in the memory cell transistor mc4 placed at an intersection of the sub word line SWL and the bit line BL2 selected in the above-described manner, a relatively large current flows through the bit line BL2. When the threshold voltage is high (data “0”), a current hardly flows through the bit line BL2. The bit line BL2 is connected to the data bus DB through a column gate (a generic name of the ½ selection circuits 211 and 213 and the ¼ selection circuit 231) and is further connected to the sense amplifier block 202. A current flowing through the bit line BL2 is amplified by the sense amplifier block 202, so that stored data is read.

The main word line MWL is shared among the plural vertical blocks BLK and drives the sub word line SWL through the sub driver 222 in each vertical block BLK. Therefore, a parasitic capacity in the main word line MWL includes a junction capacity in each sub driver 222 according to the number of stages of the vertical blocks BLK and a wiring capacity according to a wiring length. A parasitic capacity in the sub word line SWL is constant as long as the number of memory cells mc3 and so on connected at the gate thereof in the vertical block BLK is not changed.

Likewise, the bit line BL2 is shared among the plural sectors SEC and is shared among the memory cells mc1 and so on through the ½ selection circuits 211 and 213 in each sector SEC. Therefore, a parasitic capacity in the bit line BL2 includes a junction capacity in each of the ½ selection circuits 211 and 213 according to the number of stages of the sectors SEC and a wiring capacity according to a wiring length. A parasitic capacity in the bit line after passing through the ½ selection circuits 211 and 213 is constant as long as the number of memory cells mc1 and so on connected at a junction in each sector SEC is not changed.

Typically, a wiring capacity of the bit line BL2 (a second metal wiring) is larger than that of the main word line (a third metal wiring) MWL. At a reading operation, a microcurrent generated by the memory cells mc1 and so on must be flown into the bit line BL2. Therefore, the bit line BL2 should not have an excessive parasitic capacity because movement of an electric charge is hard to be recognized. For this reason, the number of stages of sectors SEC which determines the length of the bit line BL2 should be minimized.

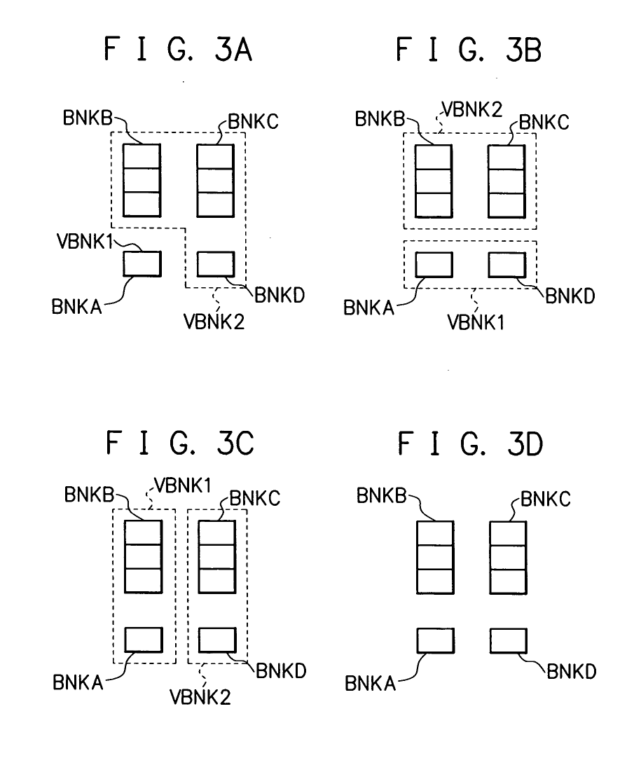

FIGS. 3A to 3D are views showing a reference example of a configuration of four types of flash memories. Each of the four types of flash memories includes four real banks BNKA, BNKB, BNKC, and BNKD. A storage capacity of each of the real banks BNKA and BNKD is equivalent to ⅛ of the entire memory area. A storage capacity of each of the real banks BNKB and BNKC is equivalent to ⅜ of the entire memory area. In other words, the storage capacity of the real banks BNKB and BNKC is three times larger than that of the real banks BNKA and BNKD. A storage capacity ratio of the four real banks BNKA to BNKD is 1:3:3:1.

The flash memory shown in FIG. 3A includes two virtual banks VBNK1 and VBNK2. The virtual bank VBNK1 is composed of one real bank BNKA. The virtual bank VBNK2 is composed of three real banks BNKB, BNKC, and BNKD. A storage capacity ratio of the virtual banks VBNK1 and VBNK2 is 1:7.

The flash memory shown in FIG. 3B includes two virtual banks VBNK1 and VBNK2. The virtual bank VBNK1 is composed of two real banks BNKA and BNKD. The virtual bank VBNK2 is composed of two real banks BNKB and BNKC. A storage capacity ratio of the virtual banks VBNK1 and VBNK2 is 2:6.

The flash memory shown in FIG. 3C includes two virtual banks VBNK1 and VBNK2. The virtual bank VBNK1 is composed of two real banks BNKA and BNKB. The virtual bank VBNK2 is composed of two real banks BNKC and BNKD. A storage capacity ratio of the virtual banks VBNK1 and VBNK2 is 4:4.

The flash memory shown in FIG. 3D includes four virtual banks BNKA to BNKD. That is, the real banks correspond to the virtual banks, respectively.

The flash memories shown in FIGS. 3A to 3C are two-bank memories composed of two virtual banks and the flash memory shown in FIG. 3D is a four-bank memory composed of four virtual banks.

Herein, each real bank is a group of memory cells actually formed in a memory area and includes at least the word driver 101, the column gate 103, and an array of the memory cells m00 to m11. The real bank is selected by a selection signal generated by decoding a bank selection address. That is, data can be read from only one real bank selected from among plural real banks.

On the other hand, the virtual bank is composed of one or plural real banks and serves as a virtual bank viewable from a system side on which a memory is mounted. Typically, a read protection during a program or erase operation is controlled in units of the virtual banks. In other words, a program operation can be performed on one virtual bank while performing a read operation on another virtual bank.

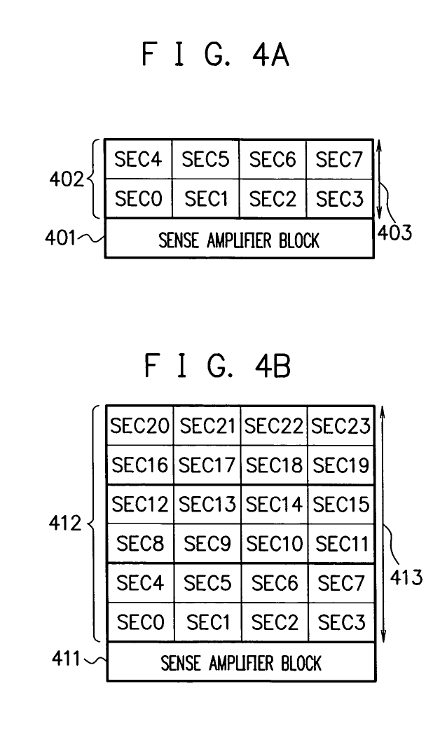

FIG. 4A is a view showing an example of a configuration of the real banks BNKA and BNKD shown in FIGS. 3A to 3D. Each of the real banks BNKA and BNKD includes a sense amplifier block 401, on which a sector array 402 is provided. In the sector array 402, 2 sectors SEC are aligned along the bit line (along a vertical direction) and 4 sectors SEC are aligned along the word line (along a horizontal direction), which sums up to 8 sectors SEC0 to SEC7.

FIG. 4B is a view showing an example of a configuration of the real banks BNKB and BNKC shown in FIGS. 3A to 3D. Each of the real banks BNKB and BNKC includes a sense amplifier block 411, on which a sector array 412 is provided. In the sector array 412, 6 sectors SEC are aligned along the bit line and 4 sectors SEC are aligned along the word line, which sums up to 24 sectors SEC0 to SEC23.

These sectors SEC are minimum units in program and erase operations. Data of one or plural sectors can be programmed or erased at the same time. A bit line length 403 of the sector array 402 shown in FIG. 4A is equivalent to a length of two sectors. A bit line length 413 of the sector array 412 shown in FIG. 4B is equivalent to a length of six sectors. In other words, a parasitic capacity ratio in the bit line of the sector arrays 402 and 412 is 1:3. In this case, a data reading speed in the bank configuration shown in FIG. 4B having a longest bit line length is the worst, and an entire access speed of the flash memory becomes low.

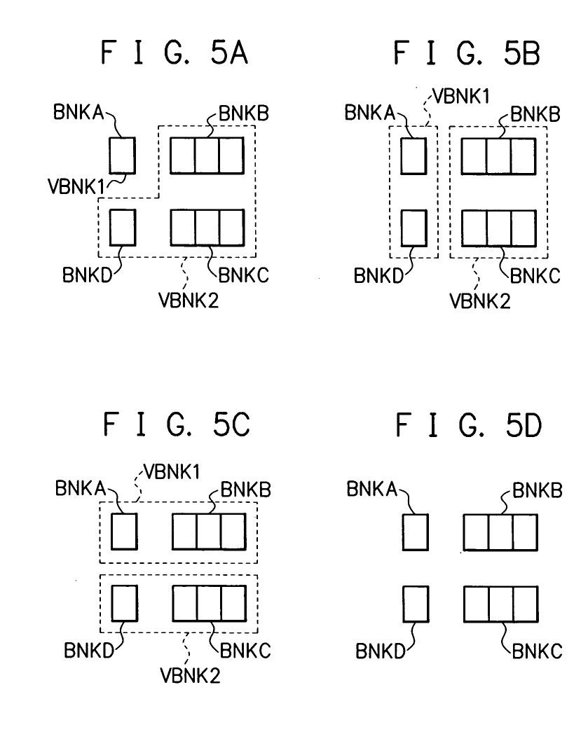

FIGS. 5A to 5D are views showing an example of a configuration of four types of flash memories according to the embodiment. The flash memories shown in FIGS. 5A to 5D are different from those in FIGS. 3A to 3D in that the bit line length is equal in all banks, but the relationship between real banks and virtual banks is the same. In other words, in FIGS. 3A to 3D, the length of the real banks BNKA and BNKD along the bit line (vertical direction) is different from that of the real banks BNKB and BNKC. In contrast to this, in FIGS. 5A to 5D, the length along the bit line (vertical direction) is equal in all of the real banks BNKA to BNKD.

In FIG. 5A, a storage capacity ratio between two virtual banks VBNK1 and VBNK2 is 1:7. In FIG. 5B, a storage capacity ratio between two virtual banks VBNK1 and VBNK2 is 2:6. In FIG. 5C, a storage capacity ratio between two virtual banks VBNK1 and VBNK2 is 4:4. In FIG. 5D, a storage capacity ratio of four banks BNKA to BNKD is 1:3:3:1.

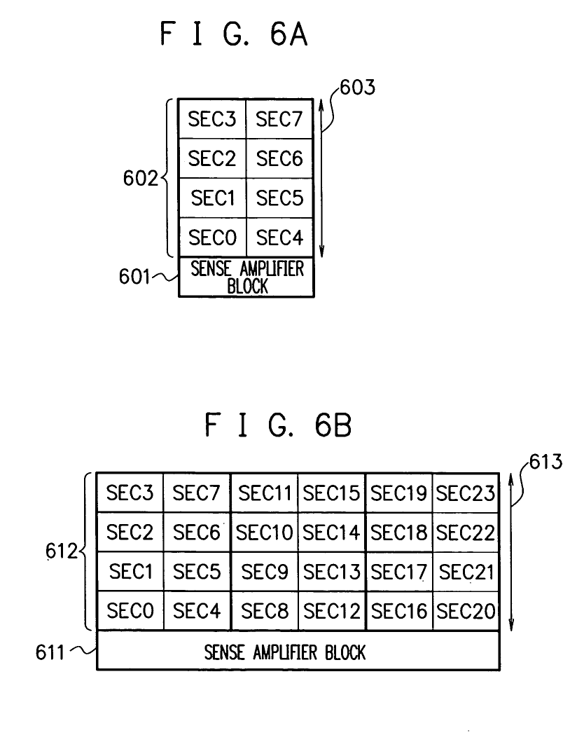

FIG. 6A is a view showing an example of a configuration of the real banks BNKA and BNKD shown in FIGS. 5A to 5D. Each of the real banks BNKA and BNKD includes a sense amplifier block 601, on which a sector array 602 is provided. In the sector array 602, 4 sectors SEC are aligned along the bit line (along a vertical direction) and 2 sectors SEC are aligned along the word line (along a horizontal direction), which sums up to 8 sectors SEC0 to SEC7.

FIG. 6B is a view showing an example of a configuration of the real banks BNKB and BNKC shown in FIGS. 5A to 5D. Each of the real banks BNKB and BNKC includes a sense amplifier block 611, on which a sector array 612 is provided. In the sector array 612, 4 sectors SEC are aligned along the bit line and 6 sectors SEC are aligned along the word line, which sums up to 24 sectors SEC0 to SEC23.

A bit line length 603 of the sector array 602 shown in FIG. 6A is equivalent to a length of four sectors. A bit line length 613 of the sector array 612 shown in FIG. 6B is also equivalent to a length of four sectors. That is, a parasitic capacity ratio in the bit line of the sector arrays 602 and 612 is 1:1. With this configuration, an access speed of the real bank shown in FIG. 6A is equal to that of the real bank shown in FIG. 6B. Accordingly, an access speed of the entire flash memory increases.

In a flash memory including the real banks shown in FIGS. 4A and 4B, a worst access speed is an access speed corresponding to the bit line length 413 of 6 sectors shown in FIG. 4B. On the other hand, in a flash memory including the real banks shown in FIGS. 6A and 6B, a worst access speed is an access speed corresponding to the bit line lengths 603 and 613 of 4 sectors shown in FIGS. 6A and 6B, realizing a higher access speed.

Incidentally, a word line length of the real bank shown in FIG. 6A is equivalent to a length of 2 sectors and a word line length of the real bank shown in FIG. 6B is equivalent to 6 sectors. That is, a parasitic capacity ratio in the word line of both banks is 1:3.

As described above, according to the embodiment, a memory device includes plural banks, and bit line lengths of all of the banks are equal to each other. Herein, bit line lengths of all of the virtual banks are equal as well as those of the real banks. In each of the plural banks, the same number of memory cells are connected to each bit line and the same number of sectors are aligned along the bit line. Each sector includes plural memory cells and serves as a unit of data erasing. The flash memory includes at least two types of real banks having different storage capacities, such as the real banks BNKA and BNKD shown in FIG. 6A and the real banks BNKB and BNKC shown in FIG. 6B.

According to the embodiment, the bit line lengths of all of the banks are equal, and thus an access speed of the entire memory device can be increased. Further, as shown in FIGS. 5A to 5D, the bit line lengths of all of the virtual banks can be made equal regardless of the form of the virtual banks, each being a combination of real banks. Accordingly, high-speed reading can be consistently performed.

A flash memory is described as an example in the above-described embodiment. However, the present invention is not limited to the flash memory, but another type of memory may be used. The memory cell may either be a nonvolatile memory cell or a volatile memory cell, but a nonvolatile memory cell is preferable.

The present embodiment is to be considered in all respects as illustrative and no restrictive, and all changes which come within the meaning and range of equivalency of the claims are therefore intended to be embraced therein. The invention may be embodied in other specific forms without departing from the spirit or essential characteristics thereof.

### INDUSTRIAL APPLICABILITY

Bit line lengths of all of banks are equal to each other, and thus an access speed of an entire memory device can be improved. Further, since bit line lengths of all of virtual banks can be made equal to each other regardless of the form of the virtual banks, each being a combination of real banks, high-speed reading can be consistently performed.

1. A memory device including plural banks, wherein
each of the plural banks comprises:
plural memory cells storing data; and
plural bit lines reading data from the plural memory cells, bit line lengths of all of the plural banks being equal to each other.

2. The memory device according to claim 1, wherein data can be read from only one bank selected from among the plural banks.

3. The memory device according to claim 1, wherein the banks are real banks.

4. The memory device according to claim 1, wherein the banks are virtual banks.

5. The memory device according to claim 3, wherein each of the real banks comprises word lines selecting the respective memory cells.

6. The memory device according to claim 5, wherein each of the real banks further comprises a word driver applying a voltage to the word lines.

7. The memory device according to claim 6, wherein each of the real banks further comprises a selection circuit connecting one or plural bit lines selected from among the plural bit lines to one or plural data buses.

8. The memory device according to claim 7, wherein each of the real banks further comprises one or plural sense amplifiers amplifying data read by said one or plural data buses.

9. The memory device according to claim 1, wherein the same number of memory cells are connected to each bit line in all of the plural banks.

10. The memory device according to claim 9, wherein the same number of sectors are aligned along the bit line in all of the plural banks.

11. The memory device according to claim 10, wherein each of the sectors includes plural memory cells and serves as a unit of data erasing.

12. The memory device according to claim 11, wherein data can be read from only one bank selected from among the plural banks.

13. The memory device according to claim 12, wherein the banks are real banks.

14. The memory device according to claim 13, wherein each of the real banks comprises word lines selecting the respective memory cells.

15. The memory device according to claim 14, wherein each of the real banks further comprises a word driver applying a voltage to the word lines.

16. The memory device according to claim 15, wherein each of the real banks further comprises a selection circuit connecting one or plural bit lines selected from among the plural bit lines to one or plural data buses.

17. The memory device according to claim 16, wherein each of the real banks further comprises one or plural sense amplifiers amplifying data read by said one or plural data buses.

18. The memory device according to claim 1, wherein the memory cells are nonvolatile memory cells.

19. The memory device according to claim 3, wherein the plural banks are at least two types of banks having different storage capacities.

20. The memory device according to claim 19, wherein the real banks are four real banks.

21. The memory device according to claim 20, wherein a storage capacity ratio of the four real banks is 1:3:3:1.

22. A memory device including plural banks, wherein
each of the plural banks comprises:
plural memory cells storing data; and
plural bit lines reading data from the plural memory cells,
the same number of memory cells being connected along the bit line in all of the plural banks.

23. The memory device according to claim 22, wherein the same number of sectors are aligned along the bit line in all of the plural banks, and each of the sectors includes plural memory cells and serves as a unit of data erasing.

24. The memory device according to claim 22, wherein bit line lengths of all of the plural banks are equal to each other.
